(19) United States
(12) Patent Application Publication
(10) Pub. No.: US 2009/0001407 A1
(43) Pub. Date: Jan. 1, 2009

(54) SEMICONDUCTOR LIGHT-EMITTING DEVICE, MANUFACTURING METHOD THEREOF, AND LAMP

(75) Inventors: Hiroshi OSAWA, Chiba-shi (JP); Naoki FUKUNAGA, Munakata-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 12/199,764

(22) Filed: Aug. 27, 2008

(30) Foreign Application Priority Data
Feb. 17, 2006 (JP) P2006-041086

(51) Int. Cl. H01L 33/00

(52) U.S. Cl. 257/99; 438/22; 257/E33.064

(57) ABSTRACT

There is provided a semiconductor light-emitting device having excellent light extraction efficiency, a manufacturing method thereof, and a lamp. A semiconductor light-emitting device 1 includes: an n-type semiconductor layer 12, a light-emitting layer 13, a p-type semiconductor layer 14, a titanium oxide-based conductive film layer 15, and a translucent film layer 16 laminated in this order, and a concavo-convex surface is formed on at least a part of the surface of the titanium oxide-based conductive film layer 15.

### BACKGROUND OF THE INVENTION

1. Field of the Invention

The present invention relates to a semiconductor light-emitting device, and particularly to a semiconductor light-emitting device having excellent light extraction efficiency, a manufacturing method thereof, and a lamp.

2. Description of Related Art

In recent years, gallium nitride (GaN)-based compound semiconductor materials, which are nitride-based semiconductors, have become of interest as a semiconductor material for producing a light-emitting device that emits light of short wavelength. A GaN-based compound semiconductor is grown on a substrate of sapphire single crystal, a variety of oxides, or a Group III-V compound, through a metal-organic chemical vapor deposition method (MOCVD method), a molecular-beam epitaxy method (MBE method), or the like.

As a structure of a general GaN-based compound semiconductor light-emitting device, if a sapphire single crystal substrate is employed, an n-type semiconductor layer, a light-emitting layer, and a p-type semiconductor layer are laminated in this order. Since the sapphire substrate is an insulator, the device structure generally has a structure as shown in FIG. 1 in which a positive electrode formed on the p-type semiconductor layer and a negative electrode formed on the n-type semiconductor layer are present in the same plane. Such a GaN-based compound semiconductor light-emitting device has two types: a face up type in which a transparent electrode is used as a positive electrode to extract light from the p-type semiconductor side; and a flip chip type in which a high reflective film of Ag or the like is used as a positive electrode to extract light from the sapphire substrate side.

For providing the transparent electrode on the p-type semiconductor, a metal transparent electrode made of Ni/Au or the like has been conventionally used. In recent years, however, in order to improve the light extraction efficiency of light-emitting devices, translucent conductive oxide films of ITO or the like have been practically and positively used at an industrial level.

External quantum efficiency is used as an index to improve the output from such a light-emitting device. It can be said that a higher external quantum efficiency means a light-emitting device with higher output.

The external quantum efficiency is represented as the multiplication of internal quantum efficiency and light extraction efficiency.

The internal quantum efficiency is the proportion of energy converted into light amongst energy of electrical current injected into the device. Meanwhile, the light extraction efficiency is the proportion of light that can be extracted to the outside amongst light generated inside the semiconductor crystal.

There are mainly two ways to improve the light extraction efficiency. The first is a method of reducing absorption of emission wavelength into an electrode, a protective film, or the like formed on the light extraction surface. The other is a method of reducing reflection loss occurring at an interface between materials having different refractive indexes, such as between a compound semiconductor, an electrode, and a protective film.

Here, one of the reasons why a metal transparent electrode of Ni/Au or the like has been replaced by a translucent conductive oxide film of ITO or the like, is that the absorption of the emission wavelength can be reduced by using the translucent conductive oxide film.

As the method of reducing reflection loss occurring at an interface between materials having different refractive indexes, there is a technique in which the light extraction surface is treated to form a concavo-convex surface. As the treatment method of forming the concavo-convex surface, there has been proposed a light-emitting device in which the compound semiconductor itself is treated to form a concavo-convex surface (for example, Patent Document 1).

However, in the light-emitting device described in Patent Document 1, since the semiconductor material is treated, the semiconductor layer is subjected to loading and is thus damaged. Therefore, although the light extraction efficiency is improved, the internal quantum efficiency is lowered, causing a problem in that the emission intensity can not be increased.

Likewise of the light-emitting device described in Patent Document 1, the light extraction efficiency of the light-emitting device can be improved by forming a concavo-convex surface on the translucent conductive oxide film. In this case, the translucent conductive oxide film undertakes a role as a light extraction layer in addition to its original role as a current diffusion layer.

However, since the refractive index of ITO is as small as 1.9, as compared to 2.6 for the GaN-based compound semiconductor, total reflection occurs at the interface between the ITO and the GaN-based compound semiconductor, which causes a problem of insufficient light extraction.

Titanium oxide has, although depending on its wavelength, a refractive index of 2.6 (wavelength 450 nm), which is approximately the same as that of the GaN-based compound semiconductor. Although titanium oxide is an insulator, it has been recently revealed to become conductive by adding Nb or the like (refer to Non-patent Document 1).

By using such conductive titanium oxide for a transparent electrode and by forming a concavo-convex surface on the titanium oxide rather than forming a concavo-convex surface on the GaN-based compound semiconductor, the light extraction efficiency of the light-emitting device can be readily improved.

Such a semiconductor light-emitting device as mentioned above is generally sealed in a resin for use as a lamp.

However, the refractive indexes of resins for use in the production of a lamp are at most about 1.5, which is greatly different from the refractive index of titanium oxide at 2.6, even if a concavo-convex shape is formed on the surface of the conductive titanium oxide. In this way, a lamp in which titanium oxide and sealing resin having greatly different refractive indexes are in contact has a problem of being incapable of sufficiently improving the light extraction efficiency.

### [Patent Document 1] Japanese Patent No. 2836687

[Non-patent Document 1] American Institute of Physics, “A Transparent metal: Nb-Doped anatase TiO₂”, Applied Physics Letter 86, 252101(2005)(US), 20 Jun. 2005, p 252101-252103

### SUMMARY OF THE INVENTION

The present invention addresses the abovementioned problems with an object of providing a semiconductor light-emitting device having excellent light extraction efficiency, a manufacturing method thereof, and a lamp, by using titanium oxide for a transparent electrode.

To solve the above problems, the inventors of the present invention have conducted intensive studies. As a result, they have completed the present invention.

That is, the present invention relates to the following.

[1] A semiconductor light-emitting device comprising an n-type semiconductor layer, a light-emitting layer, a p-type semiconductor layer, a titanium oxide-based conductive film layer, and a translucent conductive film layer laminated in this order, wherein a concavo-convex surface is formed on at least a part of the surface of the titanium oxide-based conductive film layer.
[2] The semiconductor light-emitting device according to [1], wherein the titanium oxide-based conductive film layer is of an oxide comprising Ti and at least one element selected from the group consisting of Ta, Nb, V, Mo, W, and Sb.
[3] The semiconductor light-emitting device according to either one of [1] and [2], wherein the refractive index of the translucent conductive film layer is within a range of 1.6 to 2.5.
[4] The semiconductor light-emitting device according to any one of [1] through [3], wherein the translucent conductive film layer is of a material comprising at least one selected from the group consisting of ITO (In₂O₃—SnO₂), AZO (ZnO—Al₂O₃), IZO (In₂O₃—ZnO), and GZO (ZnO—Ga₂O₃).
[5] The semiconductor light-emitting device according to any one of [1] through [4], wherein the translucent conductive film layer is formed so as to cover the titanium oxide-based conductive film layer.
[6] The semiconductor light-emitting device according to any one of [1] through [5], wherein a photocatalytic reaction-prevention layer is additionally formed so as to cover the titanium oxide-based conductive film layer and the translucent conductive film layer.
[7] The semiconductor light-emitting device according to [6], wherein the refractive index of the photocatalytic reaction-prevention layer is within a range of 1.5 to 2.0.
[8] The semiconductor light-emitting device according to either one of [6] and [7], wherein the photocatalytic reaction-prevention layer is made of silicon oxide or aluminum oxide.
[9] The semiconductor light-emitting device according to any one of [1] through [8], wherein the semiconductor light-emitting device is a nitride-based semiconductor light-emitting device.
[10] The semiconductor light-emitting device according to [9], wherein the nitride-based semiconductor light-emitting device is a GaN-based semiconductor light-emitting device.
[11] A method of manufacturing a semiconductor light-emitting device comprising an n-type semiconductor layer, a light-emitting layer, a p-type semiconductor layer, a titanium oxide-based conductive film layer, and a translucent conductive film layer laminated in this order, the method comprising forming a concavo-convex surface on at least a part of the surface of the titanium oxide-based conductive film layer.
[12] The method of manufacturing a semiconductor light-emitting device according to [11], wherein the translucent conductive film layer is formed so as to cover the titanium oxide-based conductive film layer.
[13] The method of manufacturing a semiconductor light-emitting device according to either one of [11] and [12], wherein a photocatalytic reaction-prevention layer is additionally formed so as to cover the titanium oxide-based conductive film layer and the translucent conductive film layer.
[14] The method of manufacturing a semiconductor light-emitting device according to [13], wherein the photocatalytic reaction-prevention layer is formed by a sputtering method or a CVD method.
[15] The method of manufacturing a semiconductor light-emitting device according to [14], wherein the photocatalytic reaction-prevention layer is formed by the CVD method using aluminum oxide.
[16] A lamp comprising the semiconductor light-emitting device according to any one of [1] through [10].
[17] A lamp comprising a semiconductor light-emitting device obtained by the manufacturing method according to any one of [11] through [15].

According to the semiconductor light-emitting device of the present invention, a semiconductor light-emitting device having excellent light extraction efficiency can be obtained by using a titanium oxide-based conductive film for the transparent electrode, and forming a translucent conductive film having a refractive index of 2.5 to 1.6 thereon, as the structure mentioned above.

Moreover, according to the lamp of the present invention, excellent reliability and light emission properties are provided since the semiconductor light-emitting device of the present invention is used therein.

### BRIEF DESCRIPTION OF THE DRAWINGS

FIG. 1 is a schematic diagram illustrating an example of a light-emitting device of the present invention, showing a cross-sectional structure.

FIG. 2 is a schematic diagram illustrating an example of a lamp of the present invention, showing a cross-sectional structure.

FIG. 3A is a schematic diagram illustrating the light-emitting device of the present invention, showing an example of fragmentary cross-sectional structures of the light-emitting device shown in FIG. 1.

FIG. 3B is a schematic diagram illustrating the light-emitting device of the present invention, showing another example of fragmentary cross-sectional structures of the light-emitting device shown in FIG. 1.

FIG. 3C is a schematic diagram illustrating the light-emitting device of the present invention, showing another example of fragmentary cross-sectional structures of the light-emitting device shown in FIG. 1.

FIG. 4 is a schematic diagram illustrating the light-emitting device of the present invention, showing a planar structure of the light-emitting device shown in FIG. 1.

The reference symbols shown in these figures are defined as follows:

1 . . . . Light-emitting device, 5 . . . . Lamp, 11 . . . . Substrate, 12 . . . N-type semiconductor layer, 13 . . . . Light-emitting layer, 14 . . . P-type semiconductor layer, 15 . . . . Titanium oxide-based conductive film layer, 15a . . . . Convex part, 16 . . . . Translucent conductive film layer, 17 . . . . Photocatalytic reaction-prevention layer, 18 . . . Positive electrode, 19 . . . . Negative electrode.

### BEST MODE FOR CARRYING OUT THE INVENTION

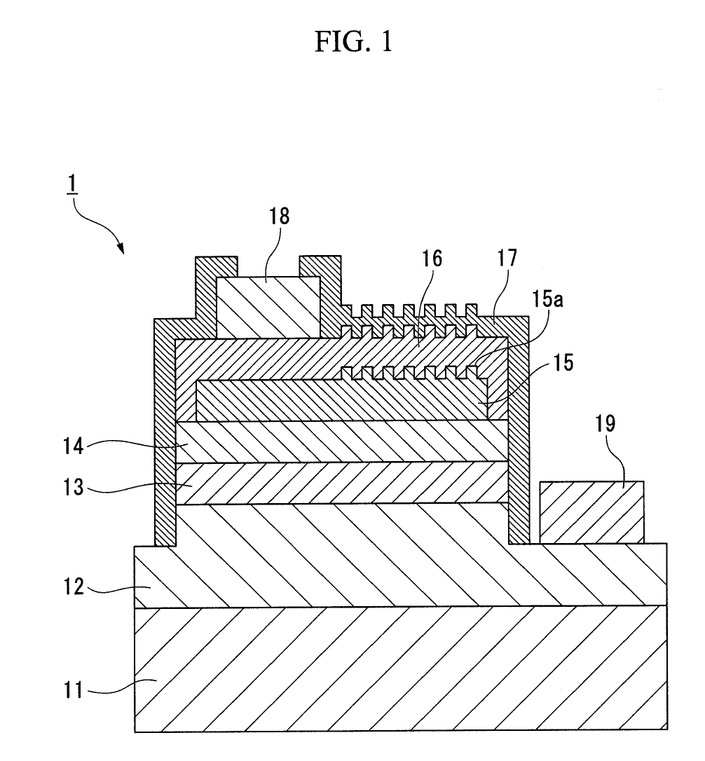

Hereunder is a description of one embodiment of a semiconductor light-emitting device of the present invention and a lamp using the same, with reference to FIG. 1 to FIG. 4.

However, it should be noted that the present invention is not to be limited by any of the following embodiment. For example, components of the embodiment may be appropriately combined.

### [Overall Structure of Semiconductor Light-Emitting Device]

FIG. 1 is a schematic diagram showing a cross-section of the semiconductor light-emitting device of the present invention.

In FIG. 1, reference symbol 11 denotes a substrate, 12 denotes an n-type semiconductor layer, 13 denotes a light-emitting layer, 14 denotes a p-type semiconductor layer, 15 denotes a titanium oxide-based conductive film layer, 16 denotes a translucent conductive film layer, 17 denotes a photocatalytic reaction-prevention layer, 18 denotes a positive electrode, and 19 denotes a negative electrode.

The semiconductor light-emitting device 1 of the present embodiment uses the titanium oxide-based conductive film layer 15 as a transparent electrode, and is schematically constituted as shown in FIG. 1, with a concavo-convex surface formed on at least a part of the surface of the titanium oxide-based conductive film layer 15.

In the semiconductor light-emitting device 1 in the example shown in FIG. 1, the translucent conductive film layer 16 is formed so as to cover the titanium oxide-based conductive film layer 15, and further has the photocatalytic reaction-prevention layer 17 formed so as to cover the titanium oxide-based conductive film layer 15 and the translucent conductive film layer 16.

Hereunder is a detailed description of the semiconductor light-emitting device 1 of the present embodiment.

### (Substrate)

The substrate 11 may be formed of a known substrate material, such as: oxide single crystals including sapphire single crystal (Al₂O₃; A-plane, C-plane, M-plane, or R-plane), spinel single crystal (MgAl₂O₄), ZnO single crystal, LiAlO₂ single crystal, LiGaO₂ single crystal, and MgO single crystal; Si single crystal; SiC single crystal; GaAs single crystal; AlN single crystal; GaN single crystal; and boride single crystals such as ZrB₂ single crystal.

In the present invention, any substrate material including these known substrate materials may be employed without limitation. Among these, sapphire single crystal and SiC single crystal are particularly preferred.

There is no particular limitation for the planar orientation of the substrate. Moreover, the substrate may be an on-axis substrate or an off-axis substrate.

### (Nitride-Based Compound Semiconductor)

On the abovementioned substrate 11 are normally laminated the n-type semiconductor layer 12 composed of a nitride-based compound semiconductor, the light-emitting layer 13, and the p-type semiconductor layer 14, through buffer layers (not shown). Moreover, the buffer layer may be unnecessary depending on the substrate to be used and the growth condition of the epitaxial layer.

For the nitride-based compound semiconductor, a variety of nitride-based compound semiconductors such as those represented by the general formula Al_{X}Ga_{Y}In_{Z}N_{1-A}M_{A} (0≦X≦1,0≦Y≦1,0≦Z≦1, and X+Y+Z=1. The symbol M represents a Group V element other than nitrogen (N). 0≦A<1) are known. In the present invention, any gallium nitride-based compound semiconductor represented by the general formula Al_{X}Ga_{Y}In_{Z}N_{1-A}M_{A} (0≦X≦1,0≦Y≦1,0≦Z≦1, and X+Y+Z=1. The symbol M represents a Group V element other than nitrogen (N). 0≦A<1), including these known nitride-based compound semiconductors, may be employed without limitation.

The nitride-based compound semiconductor may contain another Group III element other than Al, Ga, and In, and may also contain, if necessary, an element such as Ge, Si, Mg, Ca, Zn, Be, P, As, and B. Furthermore, in some cases, such nitride-based compound semiconductor contains not only intentionally added elements, but also impurities inevitably contained depending on the film formation conditions, and the like, and trace amounts of impurities contained in raw materials and reaction tube materials.

There is no particular limitation on the method of growing the nitride-based compound semiconductor, and any method known to grow nitride semiconductor may be applied. Examples thereof include MOCVD (metal organic chemical vapor deposition), HVPE (hydride vapor phase epitaxy), and MBE (molecular beam epitaxy). MOCVD is preferably employed from the viewpoints of film thickness controllability and mass productivity.

In the case of the MOCVD method, hydrogen (H₂) or nitrogen (N₂) is employed as a carrier gas, trimethylgallium (TMG) or triethylgallium (TEG) is employed as a Ga (Group III element) source, trimethylaluminum (TMA) or triethylaluminum (TEA) is employed as an Al (Group III element) source, trimethylindium (TMI) or triethylindium (TEI) is employed as an In (Group III element) source, and ammonia (NH₃), hydrazine (N₂H₄), or the like is employed as an N (Group V element) source. In addition, for the n-type dopant, monosilane (SiH₄) or disilane (Si₂H₆) may be employed as an Si source, and an organic germanium compound such as germane gas (GeH₄), tetramethylgermanium ((CH₃)₄Ge), or tetraethylgermanium ((C₂H₅)₄Ge) may be employed as a Ge source.

In the case of the MBE method, elemental germanium may also be employed as a source of dopant. For example, for the p-type dopant, bis(cyclopentadienyl)magnesium (Cp₂Mg) or bis(ethylcyclopentadienyl)magnesium ((EtCp)₂Mg) is employed as an Mg source.

The n-type semiconductor layer 12 is normally composed of an under layer, an n-contact layer, and an n-clad layer. The n-contact layer may also function as the under layer and/or the n-clad layer.

The under layer is preferably composed of an Al_{X}Ga_{1-X}N layer (0≦x≦1, preferably 0≦x≦0.5, and more preferably 0≦x≦0.1). The thickness of the under layer is preferably 0.1 μm or more, more preferably 0.5 μm or more, and most preferably 1 μm or more. By having the film thickness of 1 μm or more, the AlₓGa₁₋ₓN layer can be readily obtained with excellent crystallinity.

The under layer may be doped with an n-type impurity within a range of 1×10¹⁷ to 1×10¹⁹/cm³, although it is preferably undoped (<1×10¹⁷/cm³) in terms of maintenance of excellent crystallinity. The type of the n-type impurity is not particularly limited. Examples thereof include Si, Ge, and Sn, and preferably Si and Ge.

The temperature for growing the under layer is preferably 800° C. to 1200° C., and it is more preferably adjusted within a range of 1000° C. to 1200° C. If grown within such a temperature range, the under layer can be readily obtained with excellent crystallinity. Moreover, the inner pressure of the MOCVD growth furnace is preferably adjusted to 15 to 40 kPa.

The n-contact layer is preferably composed of an AlₓGa₁₋ₓN layer (0≦x≦1, preferably 0≦x≦0.5, and more preferably 0≦x≦0.1), similar to the under layer. Moreover, the n-contact layer is preferably doped with an n-type impurity, and contains the n-type impurity at a concentration of 1×10¹⁷ to 1×10¹⁹/cm³, and preferably 1×10¹⁸ to 1×10¹⁹/cm³, in terms of maintenance of excellent ohmic contact with the negative electrode, prevention of cracking, and maintenance of excellent crystallinity. The type of the n-type impurity is not particularly limited. Examples thereof include Si, Ge, and Sn, and preferably Si and Ge. The growth temperature is similar to the case of the under layer.

The nitride-based compound semiconductor constituting the n-contact layer preferably has the same composition as that of the under layer. The total film thickness of these layers is preferably set within a range of 1 to 20 μm, preferably 2 to 15 μm, and more preferably 3 to 12 μm. If the total film thickness of the n-contact layer and the under layer is within such a range, the crystallinity of the semiconductor can be kept excellent. The n-clad layer is preferably provided between the n-contact layer and the light-emitting layer 13. By providing the n-clad layer, a non flat portion occurring in the outer most surface of the n-contact layer can be filled. The n-clad layer can be formed of AlGaN, GaN, GaInN, or the like. Moreover, the n-clad layer may also take a superlattice structure having a heterojunction, or multiple laminations of these structures. In the case of GaInN, it is needless to say that the band gap is desirably greater than that of the GaInN of the light-emitting layer.

The thickness of the n-clad layer is not particularly limited, although it is preferably within a range of 0.005 to 0.5 μm, and more preferably 0.005 to 0.1 μm.

Moreover, the concentration of the n-type dopant in the n-clad layer is preferably within a range of 1×10¹⁷ to 1×10²⁰/cm³, and more preferably 1×10¹⁸ to 1×10¹⁹/cm³. The dopant concentration is preferably within this range in terms of maintenance of excellent crystallinity and reduction of the operating voltage for the light-emitting device.

For the light-emitting layer 13 laminated on the n-type semiconductor layer 12, there is normally employed a light-emitting layer composed of a nitride-based compound semiconductor, and preferably a nitride-based compound semiconductor made of Ga₁₋ₛInₛN (0<s<0.4).

The thickness of the light-emitting layer 13 is not particularly limited, although it is preferably a film thickness to a degree capable of providing a quantum effect, namely a critical film thickness. For example, the thickness is within a range of 1 to 10 nm, and more preferably 2 to 6 nm. The film thickness is preferably within the above range in terms of light emission output.

Moreover, the light-emitting layer may take not only a single quantum well (SQW) structure as mentioned above, but also a multiple quantum well (MQW) structure comprising the above Ga₁₋ₛInₛN as a well layer, and an Al_{c}Ga_{1-c}N (0≦c≦0.3 and b>c) barrier layer having a greater band gap energy than that of the well layer. Moreover, the well layer and the barrier layer may be doped with an impurity.

The temperature for growing the Al_{c}Ga_{1-c}N barrier layer is preferably 700° C. or more. It is more preferable to grow the barrier layer at 800° C. to 1100° C. since excellent crystallinity can be achieved. Moreover, the GaInN well layer is grown at 600° C. to 900° C., and preferably 700° C. to 900° C. That is, the growth temperature is preferably varied between layers so as to achieve excellent crystallinity of the MQW.

The p-type semiconductor layer 14 is normally composed of a p-clad layer and a p-contact layer. However, the p-contact layer may also function as the p-clad layer.

The p-clad layer is not particularly limited as long as the composition allows a greater band gap energy than that of the light-emitting layer and carrier confinement in the light-emitting layer 13 can be achieved, although Al_{d}Ga_{1-d}N (0<d≦0.4, and preferably 0.1≦d≦0.3) is preferred. The p-clad layer is preferably composed of such AlGaN in terms of carrier confinement in the light-emitting layer 13.

The thickness of the p-clad layer is not particularly limited, although it is preferably 1 to 400 nm and more preferably 5 to 100 nm.

The concentration of the p-type dopant in the p-clad layer is preferably 1×10¹⁸ to 1×10²¹/cm³, and more preferably 1×10¹⁹ to 1×10²⁰/cm³. When the p-type dopant concentration is within the above range, excellent p-type crystals can be obtained without impairing the crystallinity.

The p-contact layer is a nitride-based compound semiconductor layer comprising at least AlₑGa₁₋ₑN (0≦e≦0.5, preferably 0≦e≦0.2, and more preferably 0≦e≦0.1). The Al composition is preferably within the above range in terms of maintenance of excellent crystallinity and excellent ohmic contact with the p-ohmic electrode.

The p-type dopant is preferably contained at a concentration of 1×10¹⁸ to 1×10²¹/cm³, and more preferably 5×10¹⁹ to 5×10²⁰/cm³, in terms of maintenance of excellent ohmic contact, prevention of cracking, and maintenance of excellent crystallinity.

The type of the p-type impurity is not particularly limited, although a preferred example is Mg.

The thickness of the p-contact layer is not particularly limited, although it is preferably 0.01 to 0.5 μm and more preferably 0.05 to 0.2 μm. The film thickness is preferably within this range in terms of light emission output.

A GaN-based semiconductor is generally used for the light-emitting device, although it is also possible to use a semiconductor light-emitting device made of ZnO, Ga₂O₃, or the like rather than such a GaN-based semiconductor.

### (Titanium Oxide-Based Conductive Film Layer)

The titanium oxide-based conductive film layer of the present invention is formed directly above the p-type semiconductor layer 14 as shown in the example of FIG. 1 (refer to reference symbol 15), or above the p-type semiconductor layer 14 via a metal layer or the like.

Moreover, the titanium oxide-based conductive film layer of the present invention has a concavo-convex surface formed on at least a part of the surface thereof as shown in the example of FIG. 1 (refer to reference symbol 15).

When a metal layer is provided between the titanium oxide-based conductive film layer 15 and the p-type semiconductor layer 14, the drive voltage (Vf) of the light-emitting device can be reduced, although the transmittance decreases and the output is reduced. Accordingly, it is appropriately judged whether or not the metal layer should be provided between the titanium oxide-based conductive film layer 15 and the p-type semiconductor layer 14, while taking a balance between the drive voltage (Vf) and the output according to the intended use of the light-emitting device, or the like. The metal layer used herein is preferably made of Ni, Ni oxide, Pt, Pd, Ru, Rh, Re, Os, or the like.

For the titanium oxide-based conductive film layer, an oxide comprising Ti and at least one element selected from the group consisting of Ta, Nb, V, Mo, W, and Sb may be used.

In this case, for the composition of the titanium oxide-based conductive film layer, Ti₁₋ₓAₓO₂ (A=Ta, Nb, V, Mo, W, or Sb) is preferably used. Moreover, in this composition, X is preferably within a range of 1 to 20 at %. If X is less than 1 at %, the effect of addition is small and excellent conductivity can not be achieved. Moreover, if X exceeds 20 at %, the transmittance at the wavelength of 300 to 550 nm decreases and hence the output of the light-emitting device is reduced.

More preferably, X is within a range of 2 to 10 at %.

If Ti₁₋ₓAₓO₂ is used for the titanium oxide-based conductive film layer, the conductivity is also changed by the oxygen composition. An oxygen deficient state is preferable since the conductivity is improved. The oxygen deficient state can be made by employing various methods such as: a method in which the oxygen amount is adjusted by reactive vapor deposition or reactive sputtering with oxygen using a metal; a method in which a metal oxide tablet or target in an oxygen deficient state is used; and a method in which annealing is carried out in a reducing atmosphere of N₂ or H₂ or the like after the formation of the titanium oxide-based conductive film layer.

For the formation of the titanium oxide-based conductive film layer, any method such as a vapor deposition method, a sputtering method, a PLD method, and a CVD method may be employed.

When the vapor deposition method is employed, the film can be formed using a tablet of Ti₁₋ₓAₓO₂ (A=Ta, Nb, V, Mo, W, or Sb) by any method such as resistance heating and EB heating.

Moreover, it is also possible to form the film from respective single metal oxides in separate vapor-deposition sources.

Use of this method gives an advantage of facilitating composition control. For example, an arbitrary Ti₁₋ₓTaₓO₂ composition can be made by forming the film respectively from TiO₂ and Ta₂O₅ in separate vapor-deposition sources.

Furthermore, reactive film formation is also possible by using single or alloy metals under introduction of an oxygen gas with plasma, or the like. For example, a Ti₁₋ₓTaₓO₂ composition can be made by evaporating Ti and Ta in separate vapor-deposition sources, followed by a reaction of Ti and Ta with an oxygen gas in plasma. Moreover, in order to improve the adhesiveness and the denseness, the substrate may be heated, or ion assist may be also applied.

When the sputtering method is employed, the film can be formed using a tablet of Ti₁₋ₓAₓO₂ (A=Ta, Nb, V, Mo, W, or Sb) by any method such as RF and DC.

Moreover, it is also possible to form the film from respective single metal oxides in separate targets. Use of this method gives an advantage of facilitating composition control. For example, an arbitrary Ti₁₋ₓTaₓO₂ composition can be made by forming TiO₂ and Ta₂O₅ respectively in separate targets.

Furthermore, reactive sputtering film formation is also possible by using single or alloy metals under introduction of an oxygen gas. For example, a Ti₁₋ₓTaₓ O₂ composition can be made by electrically discharging Ti and Ta in separate targets, followed by a reaction of Ti and Ta with an oxygen gas in plasma. Moreover, in order to improve the adhesiveness and the denseness, the substrate may be heated, or biasing may also be applied.

The crystal structure of the titanium oxide-based conductive film layer is not particularly limited, although an anatase type is preferred since the conductivity is excellent.

The thickness of the titanium oxide-based conductive film layer is not particularly limited, although it is preferably within a range of 10 nm to 10 μm (10000 μm). If the thickness of the titanium oxide-based conductive film layer is less than 10 nm, the layer is too thin to provide sufficient conductivity. Moreover, the upper limit of the thickness of the titanium oxide-based conductive film layer is not particularly limited, although 10 μm is considered to be the upper limit in terms of productivity.

As with the titanium oxide-based conductive film 1 shown in FIG. 1, the titanium oxide-based conductive film is provided with a concavo-convex surface on at least a part of the surface thereof (refer to the convex parts 15a in FIG. 1). By providing concavo-convex on the surface of the titanium oxide-based conductive film, the light extraction efficiency can be improved.

The concavo-convex provided on the surface of the titanium oxide-based conductive film may be either regularly patterned, or randomly patterned.

### (Translucent Conductive Film Layer)

The translucent conductive film layer of the present invention is formed so as to cover the titanium oxide-based conductive film layer 15 as shown in the example of FIG. 1 (refer to reference symbol 16). Moreover, the translucent conductive film 16 shown in FIG. 1 has a concavo-convex surface on at least a part of the surface thereof as the underlying titanium oxide-based conductive film 15 is formed with a concavo-convex surface (refer to convex parts 15a).

The translucent conductive film layer 16 preferably has a refractive index between the refractive index of the titanium oxide-based conductive film layer 15 (refractive index of 2.6) and the refractive index of a resin, and specifically preferably within a range of 1.6 to 2.5.

The composition of the translucent conductive film layer is not specifically limited, although a material comprising at least one selected from the group consisting of ITO (In₂O₃—SnO₂), AZO (ZnO—Al₂O₃), IZO (In₂O₃—ZnO), and GZO (ZnO—Ga₂O₃) can be provided by a commonly used means well known in this technical field. Moreover, for the structure thereof, any structure including conventionally known structures may be employed without any limitation.

The refractive indexes of ITO and IZO are 1.9, and the refractive indexes of AZO and GZO are 2.1. Their refractive indexes are within a range of 1.6 to 2.5, which is advantageous for improving the light extraction efficiency.

For the formation of the translucent conductive film layer, any method such as a vapor deposition method, a sputtering method, a PLD method, and a CVD method may be employed.

In the case of the vapor deposition method, the film can be formed using a tablet of ITO, IZO, AZO, or GZO by any method such as resistance heating and EB heating. Moreover, in order to improve the adhesiveness and the denseness, the substrate may be heated or ion assist may also be applied.

In the case of the sputtering method, the film can be formed using a tablet of ITO, IZO, AZO, or GZO by any method such as RF and DC. Moreover, in order to improve the adhesiveness and the denseness, the substrate may be heated, or biasing may also be applied.

The thickness of the translucent conductive film layer is not particularly limited, although it is preferably within a range of 10 nm to 10 μm. If the thickness is less than 10 nm, the layer is too thin to contribute to improvement of the light extraction efficiency. The upper limit is not particularly limited, although 10 μm is considered to be the upper limit in terms of productivity.

Since titanium oxide has a photocatalytic action, the translucent conductive film layer is preferably formed so as to cover the titanium oxide-based conductive film as mentioned above. In particular, in this case, the contact part with the p-type semiconductor layer is increased by the contact part with the translucent conductive film layer, which is thus advantageous for reducing the drive voltage (Vf).

### (Photocatalytic Reaction-Prevention Layer)

The photocatalytic reaction-prevention layer of the present invention is formed so as to cover the titanium oxide-based conductive film layer 15 and the translucent conductive film layer 16 as shown in the example of FIG. 1 (refer to reference symbol 17).

Moreover, the photocatalytic reaction-prevention layer 17 shown in FIG. 1 has a concavo-convex surface on at least a part of the surface thereof as the underlying titanium oxide-based conductive film 15 is formed with the concavo-convex surface (refer to convex parts 15a) and further the translucent conductive film 16 is formed with the concavo-convex surface.

As generally well-known, titanium oxide has a photocatalytic action and has a property to decompose water and organic matters. The photocatalytic action is widely used in industry as one which exerts useful effects such as air purification, water purification, antifouling, and antibacterial. However, in a light-emitting device sealed in an organic substance such as a resin to constitute a lamp, there is a problem in that the sealing resin is decomposed and causes negative effects on the light-emitting device.

In a photocatalyst it is known that the photocatalytic action works with a wavelength of 380 nm or less in undoped titanium oxide, and with a wavelength of up to 500 nm in titanium oxide doped with nitrogen or tungsten.

Moreover, it is known that the quantity of light has to be several tens of μW/cm² or more for exerting the photocatalytic action. Accordingly, when titanium oxide is used in a light-emitting device having an emission wavelength of 300 to 550 nm, the situation becomes extremely easy for the titanium oxide to exert the photocatalytic action. Furthermore, when titanium oxide is used in a GaN-based light-emitting device, the device has to be used under an extremely large quantity of light of 1 W/cm², as is apparent from the fact that an emission intensity of about 10 mW can be obtained from a device of 300 μm-square.

In the case of a light-emitting device having an emission wavelength of 550 nm, the peak wavelength becomes 550 nm. However, many light-emitting devices have a wavelength distribution of constant width, even a light-emitting device having a peak wavelength of 550 nm often has a wavelength of 500 nm. Moreover, in the case of a light-emitting device having several peak wavelengths, if any of these peak wavelengths is present within a range of 300 to 550 nm, the situation becomes easy for titanium oxide to exert the photocatalytic action, which may cause concern of decomposition of the sealing resin as mentioned above.

The semiconductor light-emitting device of the present invention preferably comprises the photocatalytic reaction-prevention layer 17 in order to prevent the photocatalytic action as mentioned above.

The photocatalytic reaction-prevention layer 17 is formed on the translucent conductive film layer 16 which has been formed on the titanium oxide-based conductive film layer 15. In order to prevent the photocatalytic action through the lateral faces, it is preferably formed so as to cover the lateral faces of the titanium oxide-based conductive film 15 and the translucent conductive film layer 16.

Furthermore, as shown in the illustrated example, it is further preferable that the photocatalytic reaction-prevention layer 17 is arranged so as to cover the lateral faces of the n-type semiconductor layer 12, the light-emitting layer 13, and the p-type semiconductor layer 14, since this can prevent the photocatalytic action due to intrusion of moisture or the like from the interface between the photocatalytic reaction-prevention layer 17 and the p-type semiconductor layer 14. Moreover, in order to prevent the photocatalytic action from the joining area between the positive electrode 18 and the translucent conductive film layer 16 into the lateral faces of the positive electrode 18, then as shown in the illustrated example, it is preferable that the photocatalytic reaction-prevention layer 17 be formed so as to cover the peripheral area of the top surface of the positive electrode 18.

The photocatalytic reaction-prevention layer of the present invention has a light transmission property, in addition to the role of preventing the photocatalytic action.

The photocatalytic reaction-prevention layer of the present invention is preferably made of a translucent substance having a transmittance of 80% or more with a wavelength between 300 to 550 nm.

For the insulating transparent film used as the photocatalytic reaction-prevention layer, any substance may be employed as long as it has an insulation property and a transmittance of 80% or more with a wavelength between 300 to 550 nm. Preferable examples thereof include silicon oxide (such as SiO₂), aluminum oxide (such as Al₂O₃), hafnium oxide (such as HfO₂), niobium oxide (such as Nb₂O₅), tantalum oxide (such as Ta₂O₅), silicon nitride (such as Si₃N₄), and aluminum nitride (such as AlN). It is more preferable to employ SiO₂ or Al₂O₃, since a dense film can be readily produced through CVD film formation. It is even more preferable to form a film of Al₂O₃ through the CVD method since the reliability under high temperature and high humidity is further improved.

The photocatalytic reaction-prevention layer preferably has a refractive index within a range of 1.5 to 2.0.

Since the photocatalytic reaction-prevention layer is arranged between the translucent conductive film layer and a resin to be used for sealing in the production of the lamp, the light extraction efficiency can be improved if the refractive index is between the refractive index of the translucent conductive film layer (1.9 to 2.1) and the refractive index of the resin (to 1.5).

Accordingly, it is more preferable to use, for example, a material such as SiO₂ (refractive index of 1.5), Al₂O₃ (refractive index of 1.6), and HfO₂ (refractive index of 1.9) for the photocatalytic reaction-prevention layer, since the refractive index is between the refractive index of the translucent conductive film layer (1.9 to 2.1) and the refractive index of the resin (to 1.5).

When a film of SiO₂ is formed through CVD, there may be employed TEOS (tetraethoxysilane), TMS (trimethoxysilane), SiH₄, or the like as a raw material.

Moreover, when a film of Al₂O₃ is formed through CVD, there may be employed TMA (trimethylaluminum), DMA (dimethylaluminum), alkoxy compounds (isopropoxydimethylaluminum, sec-butoxydimethylaluminum, isopropoxydiethylaluminum, and tert-butoxydimethylaluminum), or the like as a raw material.

Furthermore, the photocatalytic reaction-prevention layer needs to be a dense film. In order to produce the abovementioned silicon oxide film, there is employed a method using a liquid coating material such as SOG (spin-on glass). However, this method is not suitable for the photocatalytic reaction-prevention layer of the present invention, since a dense film is hardly formed and moisture remains in the film even if annealed.

For the formation of the photocatalytic reaction-prevention layer, a film formation method capable of producing dense films, such as sputtering and CVD, may be employed. In particular, CVD is preferably employed since denser films can be produced.

The thickness of the photocatalytic reaction-prevention layer is not particularly limited, although it is preferably within a range of 10 nm to 10 μm (10000 nm). If the thickness of the photocatalytic reaction-prevention layer is less than 10 nm, the layer is too thin to prevent moisture intrusion. Moreover, the upper limit of the thickness of the photocatalytic reaction-prevention layer is not particularly limited, although 10 μm is considered to be the upper limit in terms of productivity.

Furthermore, the photocatalytic action of the titanium oxide-based conductive film can be weakened by doping the titanium oxide-based conductive film with iron, aluminum, magnesium, zirconium, or the like. Therefore, the structure may be such that the abovementioned photocatalytic reaction-prevention layer is provided after doping with such an element.

However, the dose of such an element which weakens the photocatalytic action as mentioned above needs to be within a range that would not remarkably spoil the conductivity and transmittance of the titanium oxide-based conductive film.

### (Positive Electrode and Negative Electrode)

The positive electrode 18 is a bonding pad provided on the titanium oxide-based conductive film 15. In the example shown in FIG. 1, the lateral faces and peripheral area of the top surface are covered by the photocatalytic reaction-prevention layer 17.

For the material of the positive electrode 18, various structures using Au, Al, Ni, Cu, and the like are well known. These well known materials and structures may be employed without any limitation.

The thickness of the positive electrode 18 is preferably within a range of 100 nm to 10 μm. Moreover, in terms of the property of the bonding pad, the thickness is preferably larger since the bondability becomes higher. Therefore, the thickness of the positive electrode 17 is more preferably 300 nm or more. Furthermore, the thickness is preferably 3 μm or less in terms of the production cost.

As shown in the illustrated example of FIG. 1, the negative electrode 19 is a bonding pad formed to be in contact with the abovementioned n-type semiconductor layer 12 of the gallium nitride-based compound semiconductor in which the n-type semiconductor layer 12, the light-emitting layer 13, and the p-type semiconductor layer 14 are sequentially laminated on the substrate 11.

Therefore, for forming the negative electrode 19, a part of the light-emitting layer 13 and the p-type semiconductor layer 14 is removed to expose the n-contact layer of the n-type semiconductor layer 12, and the negative electrode 19 is formed thereon.

For the material of the negative electrode 19, negative electrodes of various compositions and structures are well known. These well known negative electrodes may be employed without any limitation, and can be provided through a commonly used means which is well known in this technical field.

### [Method of Forming Regular Concavo-Convex on Titanium Oxide-Based Conductive Film Layer]

As the method of forming a regular concavo-convex pattern on the surface of the titanium oxide-based conductive film layer of the present invention as shown in FIG. 1 (refer to the convex parts 15a), already known photolithography may be employed. Furthermore, nanoimprint lithography may also be employed.

When nanoimprint lithography is employed, a nickel mask or the like is used, a resist is applied on this mask, and the resist face is pressed against the surface of the titanium oxide-based conductive film to effect transcription. The following steps are the same as those of already known photolithography.

When such nanoimprint lithography is employed, since a mask applied with a resist is directly pressed against the titanium oxide-based conductive film, damage to the mask may be a problem. In order to avoid this problem, there is an effective method in which a replica of the mask is formed from a water soluble resin such as PVA, a resist is applied on the replica, and the replica is pressed against the titanium oxide-based conductive film layer to effect transcription. Since this method is an indirect transcription method from the mask, the mask is not damaged. Moreover, since PVA is a resin, the mask is hardly damaged during the production of the replica. Furthermore, although the replica is to be used only once, mass production thereof is not a problem since PVA is inexpensive. Moreover, since the replica is water soluble, there is an advantage in that the replica can be readily removed with water after transcription of the resist.

The shape of the convex part is not specifically limited, although various shapes such as polygonal columns including a round column, a triangular prism, and a quadrangular prism, polygonal pyramids including a cone, a triangular pyramid, and a quadrangular pyramid can be enumerated, and the shape may be appropriately selected. Moreover, in the cross-section of the semiconductor light-emitting device 1 shown in FIG. 1, the bottom end width of the convex part 15a is preferably the same or greater than the top end width thereof.

Moreover, the size of the convex part is not specifically limited, although the diameter of the bottom face of the convex part is preferably within a range of 0.1 μm to 10 μm.

Although it is possible to make the diameter of the bottom face of the convex part to be less than 0.1 μm through photolithography, the cost is increased. Moreover, since the size of the light-emitting device is generally 100 μm to 2000 μm, if the diameter of the bottom face of the convex part exceeds 10 μm, the size becomes too large to provide a sufficient light extraction efficiency. More preferably, the size is within a range of 0.1 μm to 2 μm.

The interval between convex parts is not specifically limited as long as they are regularly arranged, although a range of 0.1 μm to 10 μm is preferred.

Although it is possible to make the interval between convex parts to be less than 0.1 μm through photolithography, the cost is increased. Moreover, since the size of the light-emitting device is generally 100 μm to 2000 μm, if the interval between convex parts exceeds 10 μm, the interval becomes too large to provide a sufficient light extraction efficiency. More preferably, the interval is within a range of 0.1 μm to 2 μm.

The height of the convex part is not specifically limited, although it is preferably within a range of 0.1 μm to 2.0 μm.

If the height of the convex part is less than 0.1 μm, the height is insufficient to contribute to the improvement of the light extraction efficiency. Moreover, if the height of the convex part exceeds 2.0 μm, the height is able to contribute to the improvement of the light extraction efficiency, but is not suitable since the productivity is greatly lowered.

More preferably, the size of the convex part satisfies the relation of (diameter of bottom face of convex part)<(height of convex part). This relation is able to more effectively improve the light extraction efficiency.

### [Method of Forming Random Concavo-Convex on the Surface of the Titanium Oxide-Based Conductive Film Layer (1)]

As the method of forming a random concavo-convex shape on the surface of the titanium oxide-based conductive film layer, photolithography and nanoimprint lithography can be employed, although for example, a method including the following steps of (1) to (3) can be enumerated as a method capable of forming concavo-convex at low cost:

a step (1) of laminating an n-type semiconductor layer composed of a semiconductor, a light-emitting layer, a p-type semiconductor layer, and a titanium oxide-based conductive film layer in this order, on a substrate;

a step (2) of forming a mask made of fine metal particles on the titanium oxide-based conductive film layer; and

a step (3) of dry etching the titanium oxide-based conductive film layer from above the mask.

In the above method, a concavo-convex surface on the titanium oxide-based conductive film layer is formed by forming a mask made of fine metal particles (i.e. metal microparticles) on a concavo-convex surface treatment area in the surface of the titanium oxide-based conductive film layer, and by dry etching the titanium oxide-based conductive film layer from thereabove. By so doing, random concavo-convex can be formed.

First is a description of the shape of the mask of fine metal particles.

In the present example, since the shape of the concavo-convex on the titanium oxide-based conductive film layer is defined by the shape of the mask of fine metal particles, then the shape of the concavo-convex on the titanium oxide-based conductive film layer can be controlled by controlling the shape of the mask of fine metal particles. In particular, the thickness of the mask of fine metal particles greatly affects the shape of the concavo-convex on the titanium oxide-based conductive film layer.

For the formation of the mask of fine metal particles, the thickness of the metal thin film to be formed on the surface of the titanium oxide-based conductive film layer prior to the heat treatment step is preferably within a range of 0.005 μm to 1 μm.

Although the optimum value of the film thickness varies depending on the mask material and the sealing resin material for making a lamp, if it is less than 0.005 μm, the film does not function as a mask, and effective concavo-convex for light extraction can not be formed on the titanium oxide-based conductive film layer. Moreover, if the film thickness exceeds 1 μm, the aggregating effect is decreased, and effective concavo-convex for light extraction can not be formed on the titanium oxide-based conductive film layer, similarly to the above.

The density of the fine metal particles in the mask is preferably within a range of 1 ×10⁵/mm² to 1×10⁸/mm². If it is within this range, concavo-convex for effectively improving the light extraction efficiency can be formed on the titanium oxide-based conductive film layer. More preferably, the density is within a range of 1×10⁶/mm² to 1×10⁷/mm².

Next is a description of the shape of the concavo-convex to be formed on the titanium oxide-based conductive film layer by dry etching.

The mean value of the center-to-center distance between convex parts defined by the peak-to-peak distance between convex parts on the titanium oxide-based conductive film layer is preferably within a range of 0.01 μm to 3 μm.

If the mean value of the center-to-center distance between convex parts is less than 0.01 μm, the convex parts are so dense that the light extraction efficiency is lowered. Moreover, if the mean value of the center-to-center distance between convex parts exceeds 3 μm, the distance becomes too large to provide a sufficient light extraction efficiency. A more preferable range of the mean value of the center-to-center distance between convex parts is 0.1 μm to 2 μm. Within this range, the light extraction efficiency is effectively improved.

The mean value of the diameter of the bottom face of the convex part on the titanium oxide-based conductive film layer is preferably within a range of 0.01 to 3 μm. With this range, the light extraction efficiency is effectively improved.

Moreover, if the mean value of the diameter of the bottom face of the convex part is less than 0.01 μm, the diameter becomes too small to contribute to the improvement of the light extraction efficiency. Moreover, if the mean value of the diameter of the bottom face of the convex part exceeds 3 μm, the diameter becomes too large to provide a sufficient light extraction efficiency. A more preferable range of the mean value of the diameter of the bottom face of the convex part is 0.1 μm to 2 μm.

The mean value of the height of the convex parts on the titanium oxide-based conductive film layer is preferably within a range of 0.1 μm to 2.0 μm.

If the mean value of the height of the convex parts is less than 0.1 μm, the height is insufficient to contribute to an improvement of the light extraction efficiency. Moreover, if the mean value of the height of the convex parts exceeds 2.0 μm, the height is able to contribute to an improvement of the light extraction efficiency, but is not suitable since the productivity is greatly lowered.

More preferably, the size of the convex parts satisfies the relation of (diameter of bottom face of convex part)<(height of convex part). This relation is able to more effectively improve the light extraction efficiency.

Next is a description of the method of forming a concavo-convex surface treatment area in the abovementioned specific shape on the titanium oxide-based conductive film layer.

In the present invention, the concavo-convex surface treatment area on the titanium oxide-based conductive film layer can be formed by forming a mask made of fine metal particles on the surface of the titanium oxide-based conductive film layer of the concerned area, and dry etching the titanium oxide-based conductive film layer from thereabove.

For the material of fine metal particles to be used for the mask, spherically-shaped fine particles with excellent aggregating property are preferred. Examples of such a metal include Ni and Ni alloy. Moreover, for the material of fine metal particles suitable for improving the efficiency of the process as well as having the aggregating property, low melting point metals or low melting point alloys containing at least one type of metal selected from Ni, Au, Sn, Ge, Pb, Sb, Bi, Cd, and In, and having a melting point between 100° C. to 450° C. can be enumerated. Among these metal materials, an AuSn alloy, an AuGe alloy, an AuSnNi alloy, and an AuGeNi alloy are preferably used, and most preferable is the AuSn alloy.

The AuSn alloy is known to become eutectic at a temperature of about 190° C. to 420° C., if the Sn composition ratio is within a range of about 10 mass % to 35 mass %. It is also known that, if the temperature goes above this range, the alloy layer generally takes an aggregated form.

For the formation of the mask of fine metal particles, first, a metal thin film is formed using a generally known vacuum vapor deposition apparatus.

The thickness of the metal thin film is preferably 50 A or more but 1000 A or less.

Moreover, use of a sputtering instrument or the like is not a problem as long as the thickness of the metal thin film can be evenly controlled within the above range.

In order to obtain a mask made of fine metal particles, generally a heat treatment within a temperature range of 100° C. to 600° C. for 1 minute or more is applied on the formed metal thin film, although the condition depends on the metal to be used.

The shape of the mask of fine metal particles after the heat treatment varies depending on the oxygen concentration in the heat treatment atmosphere. By controlling the oxygen concentration according to the material to be used, a mask of fine metal particles capable of forming a concavo-convex pattern of a shape suitable for improving the light extraction efficiency on the titanium oxide-based conductive film can be obtained. Moreover, the heat treatment may also be preferably performed under an atmosphere without any oxygen at all, in some cases depending on the material of the fine metal particles to be used.

After the formation of the mask of fine metal particles, a concavo-convex surface in the abovementioned specific shape can be formed by dry etching the titanium oxide-based conductive film layer from above the mask. For the dry etching, a typical dry etching of a reactive ion etching (RIE) type can be employed. For the gas species, any gas may be used without limitation, although etching with use of a chlorine-containing gas is preferred. In order to avoid the change in the shape of metallic aggregate (shape of fine metal particles) due to heat, the substrate temperature is desirably kept at 100° C. or less.

### [Method of Forming Random Concavo-Convex on the Surface of the Titanium Oxide-Based Conductive Film Layer (2)]

As another method of forming a random concavo-convex shape on the titanium oxide-based conductive film layer, there can be enumerated a method in which the titanium oxide-based conductive film is formed by forming two separate layers of a current diffusion layer and a light extraction layer, and subsequently the light extraction layer is mainly etched.

The current diffusion layer is composed of a titanium oxide-based conductive film having a current diffusion function, and is formed right above the p-type semiconductor layer, or above the p-type semiconductor layer via a metal layer or the like. When a metal layer is provided between the current diffusion layer and the p-type semiconductor layer, the drive voltage (Vf) of the light-emitting device can be reduced, although the transmittance decreases and the output is reduced. Accordingly, it is appropriately judged whether or not the metal layer or the like should be provided between the current diffusion layer and the p-type semiconductor layer, while taking a balance between the drive voltage (Vf) and the output according to the intended use of the light-emitting device, or the like. When a metal layer is provided between the current diffusion layer and the p-type semiconductor layer, the metal layer to be used is preferably made of Ni, Ni oxide, Pt, Pd, Ru, Rh, Re, Os, or the like.

The current diffusion layer may be formed by any method as long as the current diffusion function can be achieved.

Moreover, the current diffusion layer is preferably formed by the following two methods, for example. The first is a film formation method by sputtering method. The other is a film formation method by a vacuum vapor deposition method.

The sputtering method can provide a dense film with excellent crystallinity since the energy of the sputtered particles at the time of sputtering is large. As the crystallinity of the titanium oxide-based conductive film becomes higher, the current diffusion layer becomes more difficult to etch and becomes more difficult to erode at the time of etching, and hence the current diffusion property becomes more difficult to deteriorate by etching.

In the vacuum vapor deposition method, the obtained film composed of the titanium oxide-based conductive film is in an amorphous state, or with low crystallinity, since the energy of particles at the time of vapor deposition is not so large.

However, a dense film with excellent crystallinity can be obtained by forming a film at a temperature of 300° C. to 800° C. during vapor deposition, or applying a heat treatment at 300° C. to 800° C. after the film formation.

If the heat treatment temperature is less than 300° C., the effect of improving crystallization is small. If the temperature exceeds 800° C., the nitride-based semiconductor device is damaged.

The titanium oxide-based conductive film constituting the current diffusion layer may take any crystalline state, although a columnar crystal is preferred since it is hard to etch.

If the thickness of the current diffusion layer is too thin, the current diffusion property is lowered and thus it is not preferable. Moreover, if the thickness of the current diffusion layer is too thick, the transmittance is worsened and the output is reduced. Accordingly, the thickness of the current diffusion layer is within a range of 35 nm to 2000 nm, more preferably 50 nm to 1000 nm, and most preferably 100 nm to 500 nm.

The light extraction layer is composed of a titanium oxide-based conductive film having a light extraction function, and is formed on the current diffusion layer. The structure may be either such that the light extraction layer is formed right above the current diffusion layer, or such that a metal layer or the like is arranged between the light extraction layer and the current diffusion layer.

In order to reduce the drive voltage (Vf) of the light-emitting device, a metal layer or the like may be formed between the light extraction layer and the current diffusion layer as mentioned above. However, since there is a risk of reducing the transmittance of the light-emitting device and reducing the output, it is necessary to determine a balance according to the intended use. When a metal layer is provided between the light extraction layer and the current diffusion layer, the metal layer to be used is preferably made of Ni, Ni oxide, Pt, Pd, Ru, Rh, Re, Os, or the like.

The top surface of the light extraction layer is preferably in a concavo-convex shape so as to improve the light extraction efficiency.

As the method of forming the concavo-convex shape, any already known etching method such as wet etching and dry etching may be applied, although wet etching is preferably employed since the etching speed is greatly changed depending on the crystalline state of the titanium oxide-based conductive film. A regular concavo-convex shape may be formed using a mask, while a random concavo-convex shape may also be formed by etching alone.

When wet etching is performed, hydrofluoric acid, phosphoric acid, sulfuric acid, hydrochloric acid, hydrofluoric acid/nitric acid mixture, hydrofluoric acid/hydrogen peroxide mixture, hydrofluoric acid/ammonium fluoride mixture, hydrofluosilicic acid, or the like may be employed as an etching liquid, although hydrofluoric acid, hydrofluoric acid/nitric acid mixture, hydrofluoric acid/hydrogen peroxide mixture, hydrofluoric acid/ammonium fluoride mixture, and hydrofluosilicic acid (H₂SiF₆) are more preferably employed.

The light extraction layer of the present invention is preferably composed of a material having a higher etching speed than that of the material used for the aforementioned current diffusion layer. Moreover, the light extraction layer may take any crystalline state, although granular crystal is preferred since it is easy to etch.

Furthermore, as the method of forming the light extraction layer, it is desirable to employ a method in which the formation can be performed at a higher etching speed for etching the light extraction layer than the etching speed for the current diffusion layer. Specifically, as the method of forming the light extraction layer, for example, a vacuum vapor deposition method is preferably employed since the film in an amorphous state, or with low crystallinity, can be obtained.

If the thickness of the light extraction layer is too thin, the elevation difference between the concave part and the convex part constituting the concavo-convex shape formed on the top surface of the light extraction layer becomes too small to provide a sufficient light extraction efficiency. Moreover, if the thickness of the light extraction layer is too thick, the transmittance is worsened and the output is reduced.

The thickness of the etched light extraction layer which satisfies this property is within a range of 35 nm to 2000 nm, preferably 50 nm to 1 μm, and more preferably 100 nm to 500 nm. The thickness of the light extraction layer is defined as the height from the surface (bottom face) of the light extraction layer on the current diffusion layer side to the apex of the convex part.

The elevation difference between the concave part and the convex part constituting the concavo-convex shape on the light extraction layer is preferably within a range of 35 nm to 2000 nm (2 μm), more preferably 50 nm to 1 μm, and most preferably 100 nm to 500 nm.

If the elevation difference between the concave part and the convex part is too small, a sufficient light extraction efficiency can not be obtained. Moreover, if the elevation difference between the concave part and the convex part is too large, the thickness of the light extraction layer becomes so thick that the transmittance is worsened and the output is reduced. The elevation difference between the concave part and the convex part is defined as the height from the bottom of the concave part to the apex of convex part.

[Method of Forming Random Concavo-Convex on the Surface of the Titanium Oxide-Based Conductive Film Layer (3)]

As another method of forming a random concavo-convex shape on the titanium oxide-based conductive film layer, there can also be enumerated a method in which the surface of the titanium oxide is roughened using a laser.

For the laser, a laser having a wavelength such that the laser beam can be absorbed into the titanium oxide-based conductive film is preferred. The spectral absorptance of the titanium oxide-based conductive film varies depending on the crystal system and additives, although light above the band gap can be absorbed therein. For example, in the case of TiO₂, the band gap is 3.2 and thus a wavelength of 380 nm or shorter is preferred since such laser beams can be absorbed.

Any laser can be employed as long as the laser has a wavelength of 380 nm or shorter, although a YAG third harmonic laser (wavelength of 355 nm), a YAG fourth harmonic laser (wavelength of 266 nm), a XeCl excimer laser (wavelength of 308 nm), a KrF excimer laser (wavelength of 248 nm), an ArF excimer laser (wavelength of 193 nm), and an F₂ excimer laser (wavelength of 157 nm) are preferably employed. Excimer lasers are more preferably employed since the irradiation area can be enlarged.

When the KrF excimer laser is employed, the energy density is preferably within a range of 50 to 2000 mJ/cm². If it is less than 50 mJ/cm², the energy density is too small to roughen the surface of the titanium oxide-based conductive film. If it exceeds 2000 mJ/cm², the energy density becomes so large that the conductivity of the titanium oxide-based conductive film is spoiled.

The concavo-convex obtained by the laser irradiation is random, although the elevation difference between the concave part and the convex part constituting the concavo-convex shape is preferably within a range of 35 nm to 2000 nm, more preferably 50 nm to 1 μm, and most preferably 100 nm to 500 nm.

If the elevation difference between the concave part and the convex part is too small, a sufficient light extraction efficiency can not be obtained. Moreover, if the elevation difference between the concave part and the convex part is too large, the thickness of the titanium oxide-based conductive film becomes so thick that the transmittance is worsened and the output is reduced. The elevation difference between the concave part and the convex part is defined as a height from the bottom of the concave part to the apex of the convex part.

Moreover, laser irradiation is also capable of improving the light transmittance and the conductivity of the titanium oxide-based conductive film, in addition to being capable of roughening of the titanium oxide-based conductive film. Accordingly, several processes including roughening, improvement of the transmittance, and improvement of the conductivity can be performed in a single process with use of laser irradiation.

### [Step Coverage]

When a concavo-convex shape is formed on the titanium oxide-based conductive film, the step coverage of a film formed thereon becomes a problem. For example, if the slope of the concavo-convex is too steep, if the aspect ratio is too large, or if the size of the concavo-convex is too small, then the film to be formed on the titanium oxide-based conductive film is not formed along the profile of the concavo-convex and generates a gap. If a gap is generated, the refractive index in that area becomes 1, which causes a lowering of the light extraction efficiency.

As the film formation method for improving the step coverage, a CVD method and a sputtering method are suitable. When a film is formed by the sputtering method, it is more preferable to employ a method in which a high frequency power source (13 MHz or more, and more preferably 60 MHz±10 MHz) is used for the sputter source which biases the surface of the formed film.

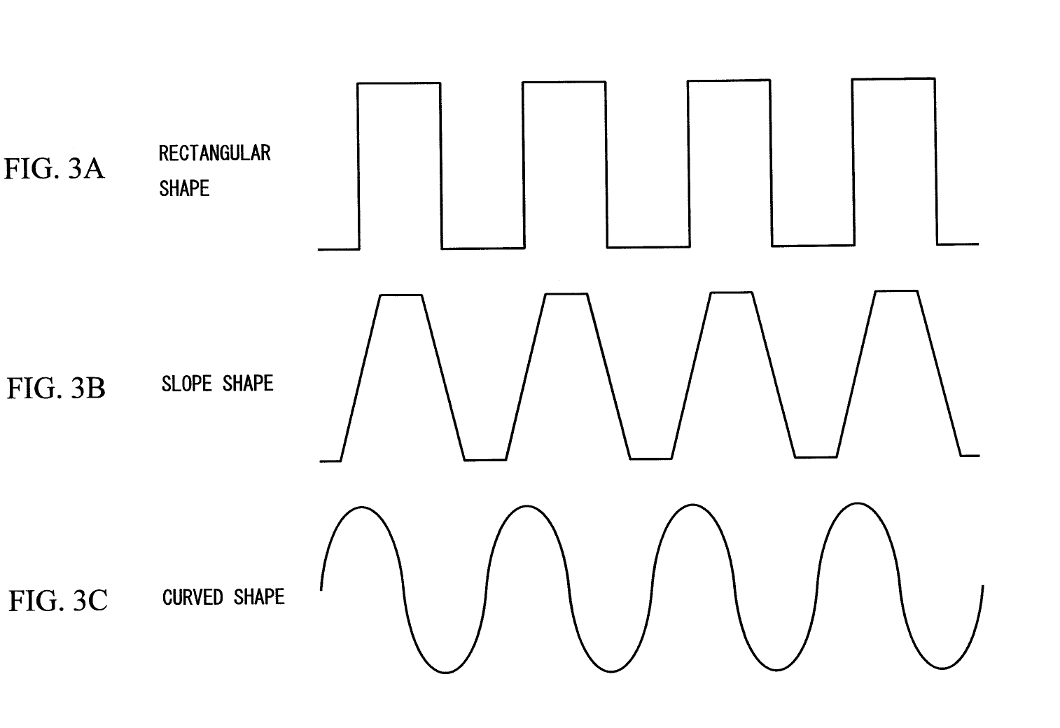

With respect to the shape of the concavo-convex, rectangular convex parts as shown in FIG. 3A are not capable of providing excellent step coverage. In order to obtain excellent step coverage, the bottom end dimension of the convex part is preferably greater than the top end dimension thereof. A shape in which the dimension is gradually tapered from the bottom end to the top end is more preferred.

Specifically preferred examples thereof include slope-shaped convex parts as shown in FIG. 3B and curved-shaped convex parts as shown in FIG. 3C. In the case of the slope-shaped convex parts, the inclination with respect to the normal line of the substrate is preferably 5 degrees or more, since the step coverage is improved. However, if the inclination with respect to the normal line of the substrate is too large, it is difficult to obtain the aspect ratio. Therefore, the angle is preferably set to 60 degrees or less.

### [Structure of Lamp]

The light-emitting device of the present invention may be constituted as an LED lamp using a method known to those skilled in the art, without any limitation.

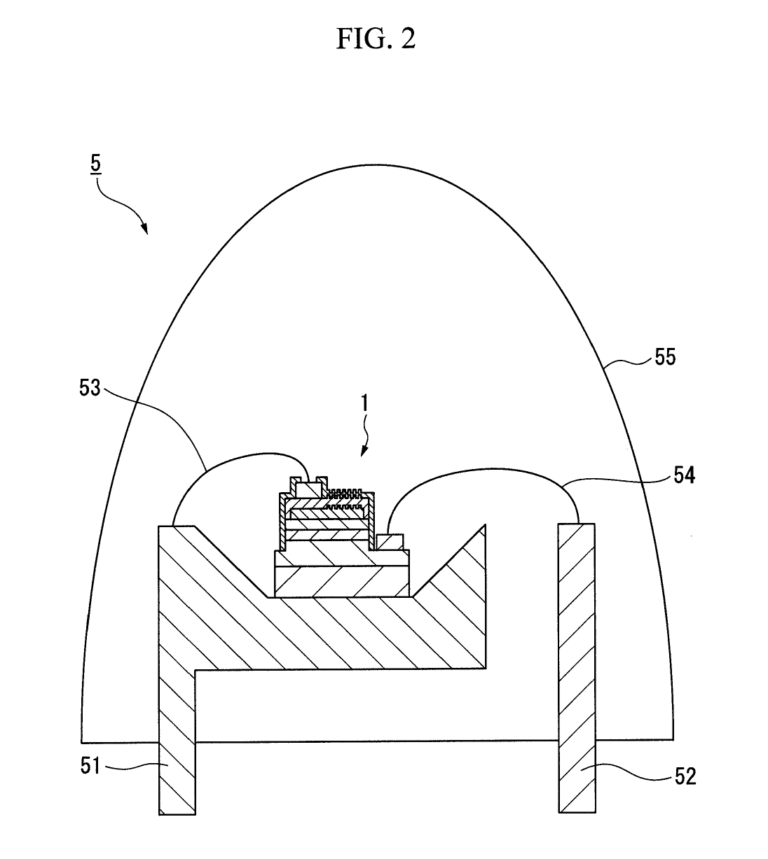

FIG. 2 is a cross-sectional view which schematically illustrates an example of a lamp of the present invention. This lamp 5 comprises the semiconductor light-emitting device 1 composed of the face-up type nitride-based semiconductor of the present invention shown in FIG. 1, mounted in a projectile shape. In FIG. 2, reference symbols 51 and 52 denote frames, reference symbols 53 and 54 denote wires, and reference symbol 55 denotes a mold.

The lamp 5 can be produced using the semiconductor light-emitting device 1 of the present invention shown in FIG. 1, by an already known method. Specifically, for example, the projectile-shaped lamp shown in FIG. 2 can be produced by the following manner. The semiconductor light-emitting device 1 is adhered onto either one of the two frames 51 and 52 (frame 51 in FIG. 2) with a resin or the like. The positive electrode and the negative electrode of the semiconductor light-emitting device 1 (refer to reference symbols 18 and 19 shown in FIG. 1) are respectively joined to the frames 51 and 52 with the wires 53 and 54 made of a material such as gold. Then, the surroundings of the light-emitting device 1 are molded with a mold 55 made of a transparent resin.

The lamp of the present invention is not limited to the above structure, and for example a white lamp may also be constituted by a combination of the light-emitting device of the present invention and a cover having a fluorescent substance.

Moreover, the lamp of the present invention may be used for any application, such as a projectile type for general use, a side view type for use in a portable back light, and a top view type for use in an indicator.

Since the light-emitting device of the present invention is highly reliable with excellent light extraction efficiency, a lamp with excellent light emission properties can be realized.

### EXAMPLES

Next is a more detailed description of the light-emitting device of the present invention and a lamp using the same, with reference to Examples. It should be noted that the present invention is not to be limited to these Examples.

### Experimental Example 1

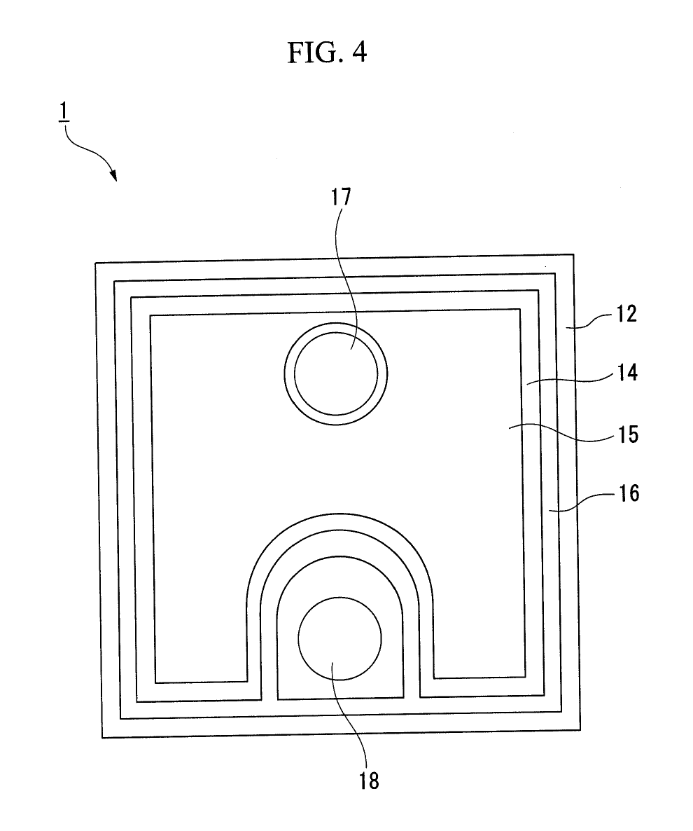

FIG. 1 shows a cross-sectional schematic diagram of a gallium nitride-based compound semiconductor light-emitting device produced in the present Experimental Example. FIG. 4 shows a planar schematic diagram thereof.

(Production of gallium nitride-based compound semiconductor light-emitting device)

On a substrate 11 made of sapphire was laminated a gallium nitride-based compound semiconductor layer via a buffer layer made of AlN. This gallium nitride-based compound semiconductor layer comprised:

an n-type semiconductor layer 12 in which an under layer of undoped GaN in a thickness of 8 μm, a Ge-doped n-type GaN-contact layer in a thickness of 2 μm, and an n-type In_{0.1}Ga_{0.9}N-clad layer in a thickness of 0.02 μm were laminated in this order;

a light-emitting layer 13 of a multiple quantum well structure obtained by five laminations of a Si-doped GaN barrier layer in a thickness of 16 nm and an In_{0.06}Ga_{0.94}N well layer in a thickness of 2.5 nm with a barrier layer on the top; and

a p-type semiconductor layer 14 in which a Mg-doped p-type Al_{0.07}Ga_{0.93}N-clad layer in a thickness of 0.01 μm and a Mg-doped p-type Al_{0.02}Ga_{0.98}N-contact layer in a thickness of 0.18 μm were laminated in this order.

These respective layers were laminated in this order to form the gallium nitride-based compound semiconductor layer. The light extraction surface was set on the semiconductor side.

In this structure, the carrier density of the n-type GaN-contact layer was 1×10¹⁹ cm⁻³, the Si dope amount of the GaN barrier layer was 1×10¹⁷ cm⁻³, the carrier density of the p-type AlGaN-contact layer was 5×10¹⁸ cm⁻³, and the Mg dope amount of the p-type AlGaN-clad layer was 5×10¹⁹ cm³.

Moreover, layers of the gallium nitride-based compound semiconductor layer (reference symbols 12, 13, 14, and 15 in FIG. 1) were laminated by the MOCVD method, under usual conditions well known to those skilled in the art.

Then, this gallium nitride-based compound semiconductor layer was subjected to a reactive ion etching method to expose the n-type GaN-contact layer of an area for forming the negative electrode. In this case, first, a resist was evenly applied onto the whole surface of the p-type semiconductor layer, and then the resist was removed from the area for forming the negative electrode using a known lithography technique. Then, the resultant product was set in a vacuum vapor deposition apparatus to laminate Ni in a thickness of about 50 nm and Ti in a thickness of 300 nm by an electron beam method under a pressure of 4×10⁻⁴ Pa or less. Then, the metal films together with the resist in areas other than the area for forming the negative electrode were removed by lift-off technique.

Next, the semiconductor laminate substrate was mounted on an electrode in the etching chamber of a reactive ion etching apparatus. The pressure in the etching chamber was reduced to 10⁻⁴ Pa, and then Cl₂ as an etching gas was supplied to etch until the n-type GaN-contact layer was exposed. After etching, the resultant product was taken out from the reactive ion etching apparatus, followed by removal of the etching mask with nitric acid and hydrofluoric acid.

### (Formation of Titanium Oxide-Based Conductive Film)

Next, using a known photolithography technique and lift-off technique, a titanium oxide-based conductive film layer 15 comprising a Ni contact metal layer in a thickness of 1 nm and a layer made of Ti_{0.95}Nb_{0.05}O₂ in a thickness of 1 μm was formed only in an area for forming the positive electrode on the surface of the p-type AlGaN-contact layer (p-type semiconductor layer 14).

The titanium oxide-based conductive film layer was formed by first placing the substrate laminated with the gallium nitride-based compound semiconductor layer into a vacuum sputtering apparatus, and then the laminating Ti_{0.95}Nb_{0.05}O₂ on the p-type AlGaN-contact layer.

Then, the substrate laminated with the gallium nitride-based compound semiconductor layer was taken out from the vacuum sputtering apparatus, and was subjected to a heat treatment make it transparent.

### (Formation of Random Concavo-Convex Pattern)

Next, using a known photolithography technique, a resist film was formed on portions other than the surface of the titanium oxide-based conductive film layer, and the substrate was then placed in a vapor deposition apparatus to laminate Au/Sn in a thickness of 15 nm.

Next, in a nitrogen atmosphere, a heat treatment was performed at a temperature of 250° C. to make granular aggregations in the Au/Sn thin film so as to form a mask made of fine metal particles. The diameter of the fine metal particles was within a range of 0.2 to 1.5 μm, and a highly dense layer (mask) of fine metal particles at 2×10⁶ pieces/mm² was formed.

Next, patterning was performed using the resist film so as to expose the surface of the titanium oxide-based conductive film layer, followed by general dry etching.

Here, since the abovementioned mask of fine metal particles was formed on the area to be treated for the concavo-convex pattern, etching was selectively performed in a shape corresponding to the shape of the fine metal particles through dry etching, and the surface of the titanium oxide-based conductive film layer was successfully treated to have a curved concavo-convex pattern.

This convex part was in a round shape in the top view. The mean value of the bottom end dimension was about 0.7 μm (diameter), and the mean value of the height T was about 1.0 μm. The mean value of the distance between convex parts was 0.8 μm, and the standard deviation with respect to this value was 50%.

### (Formation of Translucent Conductive Film)

Next, using a known photolithography technique and lift-off technique, an ITO film layer made of ITO (SnO₂: 10 wt %) in a thickness of 200 nm was formed only in the area for forming the positive electrode on the concavo-convex surface-treated titanium oxide conductive film layer. The ITO film layer was formed by first placing the substrate laminated up to the titanium oxide conductive film layer in a vacuum sputtering apparatus, and then laminating ITO in a thickness of 200 nm on the titanium oxide conductive film layer.

Then, the substrate laminated with the gallium nitride-based compound semiconductor layer was taken out from the vacuum chamber, and was subjected to a heat treatment to make it transparent so as to form a translucent conductive film layer made of ITO.

### (Formation of Bonding Pad)

Next, the positive electrode (bonding pad) 18 and the negative electrode (bonding pad) 19 were formed by the following procedure.

First, normally, treatments were performed according to a known procedure called lift-off. Furthermore, a first layer comprising Au, a second layer comprising Ti, a third layer comprising Al, a fourth layer comprising Ti, and a fifth layer comprising Au were sequentially laminated on a part of the titanium oxide-based conductive film by a similar lamination method, to form a five-layered positive electrode 18. Here, the thicknesses of respective layers comprising Au/Ti/Al/Ti/Au were respectively set to 50/20/10/100/500 nm.

Next, on the n-type GaN-contact layer which had been exposed though the abovementioned reactive ion etching method, the negative electrode bonding pad was formed by the following procedure.

First, a resist was evenly applied onto the whole surface of the exposed area of the n-type GaN-contact layer, and then the resist was removed from the portion for forming the negative electrode on the exposed n-type GaN-contact layer using a known lithography technique. Then, the negative electrode comprising Ti in a thickness of 100 nm and Au in a thickness of 200 nm sequentially from the semiconductor side, was formed by a normally used vacuum vapor deposition method. The resist was then removed by a known method.

### (Formation of Photocatalytic Reaction-Prevention Layer)

Next, using a known photolithography technique and lift-off technique, a photocatalytic reaction-prevention layer made of Al₂O₃ was formed by the CVD method in a thickness of 500 nm on areas other than the central parts of the positive electrode and the negative electrode. The photocatalytic reaction-prevention layer was formed so as to cover the lateral faces of the positive electrode, the lateral faces of the negative electrode, the light-emitting layer, and the lateral faces of the n-type semiconductor.

### (Division of Device)

The wafer formed up to the photocatalytic reaction-prevention layer in this manner was ground and polished on the back face of the substrate 11 to thereby thin the thickness of the substrate 11 to 80 μm. Ruled lines were drawn using a laser scriber from the semiconductor laminate side, and the layer was pressingly broken to cut it into 350 μm-square chips.

### (Formation of Lamp)

The obtained 350 μm-square chip was mounted on a frame of a projectile-shaped lamp, followed by wire bonding. The resultant product was then sealed in an epoxy resin to make the lamp of Experimental Example 1. The refractive index of the epoxy resin was 1.5.

### (Evaluation of Device Characteristics)

The lamps of respective Experimental Examples obtained as mentioned above were measured for the light emission output and the drive voltage (Vf) using testers. The results are shown in Table 1 below.

Moreover, the semiconductor light-emitting devices of Experimental Examples 2 to 7 and Experimental Example 9 were produced in the same manner as that of Experimental Example 1, and were subjected to the same evaluations, except that the titanium oxide-based conductive film layer, the translucent conductive film layer, and the photocatalytic reaction-prevention layer were formed under the conditions shown in Table 1 below.

The semiconductor light-emitting device of Experimental Example 8 was produced in the same manner as that of Experimental Example 1, and was subjected to the same evaluations, except that the translucent conductive film layer was not formed.

The semiconductor light-emitting device of Experimental Example 10 was produced in the same manner as that of Experimental Example 1, and was subjected to the same evaluations, except that the photocatalytic action-prevention layer was not formed.

The semiconductor light-emitting device of Experimental Example 11 was produced in the same manner as that of Experimental Example 1, and was subjected to the same evaluations, except that the translucent conductive film layer and the photocatalytic action-prevention layer were not formed.

The semiconductor light-emitting device of Experimental Example 12 was produced in the same manner as that of Experimental Example 1, and was subjected to the same evaluations, except that the concavo-convex pattern was not formed on the surface of the titanium oxide-based conductive film layer.

A list of the conditions for the formation, and characteristics of the devices of the respective Experimental Examples is shown in Table 1.

TABLE 1

| | Titanium oxide-based conductive | | | Translucent conductive | | | Photocatalytic action- | | | | |
|---|---|---|---|---|---|---|---|---|---|---|---|
| | film layer | | | film layer | | | prevention layer | | | light | |
| | | | Refractive | | | Refractive | | | Refractive | emission | |
| | Composition | Thickness | index | Composition | Thickness | index | Composition | Thickness | index | output | Vf |
| Experimental | Ti_{0.95}Nb_{0.05}O₂ | 1 μm | 2.6 | ITO:SnO₂ | 200 nm | 1.9 | Al₂O₃ | 500 nm | 1.6 | 18.6 mW | 3.2 V |
| Example 1 | | | | 10 wt % | | | | | | | |
| Experimental | Ti_{0.95}Nb_{0.05}O₂ | 1 μm | 2.6 | ITO:SnO₂ | 20 nm | 1.9 | Al₂O₃ | 500 nm | 1.6 | 18.1 mW | 3.2 V |
| Example 2 | | | | 10 wt % | | | | | | | |
| Experimental | Ti_{0.95}Nb_{0.05}O₂ | 1 μm | 2.6 | ITO:SnO₂ | 100 nm | 1.9 | Al₂O₃ | 500 nm | 1.6 | 18.3 mW | 3.2 V |
| Example 3 | | | | 10 wt % | | | | | | | |
| Experimental | Ti_{0.95}Nb_{0.05}O₂ | 1 μm | 2.6 | ITO:SnO₂ | 500 nm | 1.9 | Al₂O₃ | 500 nm | 1.6 | 18.4 mW | 3.2 V |
| Example 4 | | | | 10 wt % | | | | | | | |
| Experimental | Ti_{0.95}Nb_{0.05}O₂ | 1 μm | 2.6 | AZO:Al₂O₃ | 200 nm | 2.1 | Al₂O₃ | 500 nm | 1.6 | 18.4 mW | 3.3 V |
| Example 5 | | | | 5 wt % | | | | | | | |
| Experimental | Ti_{0.95}Nb_{0.05}O₂ | 1 μm | 2.6 | IZO:ZnO | 200 nm | 1.9 | Al₂O₃ | 500 nm | 1.6 | 18.3 mW | 3.2 V |
| Example 6 | | | | 10 wt % | | | | | | | |
| Experimental | Ti_{0.95}Nb_{0.05}O₂ | 1 μm | 2.6 | GZO:Ga₂O₃ | 200 nm | 2.1 | Al₂O₃ | 500 nm | 1.6 | 18.4 mW | 3.3 V |
| Example 7 | | | | 10 wt % | | | | | | | |
| Experimental | Ti_{0.95}Nb_{0.05}O₂ | 1 μm | 2.6 | Not provided | | | Al₂O₃ | 500 nm | 1.6 | 17.4 mW | 3.3 V |
| Example 8 | | | | | | | | | | | |
| Experimental | Ti_{0.95}Nb_{0.05}O₂ | 1 μm | 2.6 | ITO:SnO₂ | 5 nm | 1.9 | Al₂O₃ | 500 nm | 1.6 | 17.5 mW | 3.3 V |
| Example 9 | | | | 10 wt % | | | | | | | |
| Experimental | Ti_{0.95}Nb_{0.05}O₂ | 1 μm | 2.6 | ITO:SnO₂ | 200 nm | 1.9 | Not provided | | | 18.1 mW | 3.2 V |
| Example 10 | | | | 10 wt % | | | | | | | |
| Experimental | Ti_{0.95}Nb_{0.05}O₂ | 1 μm | 2.6 | Not provided | | | Not provided | | | 17.0 mW | 3.3 V |
| Example 11 | | | | | | | | | | | |
| Experimental | Ti_{0.95}Nb_{0.05}O₂ | 1 μm | 2.6 | ITO:SnO₂ | 200 nm | 1.9 | Al₂O₃ | 500 nm | 1.6 | 13.3 mW | 3.3 V |
| Example 12 | | | | 10 wt % | | | | | | | |

### (Evaluation Results)

As shown in Table 1, in the semiconductor light-emitting device of Experimental Example 1, the light emission output was 18.6 mW and the drive voltage (Vf) was 3.2 V at an applied current of 20 mA before heating.

Moreover, in all of the semiconductor light-emitting devices of Experimental Examples 2 to 7 in which the translucent conductive film layer was formed similarly to Experimental Example 1, the light emission output was 18.1 mW or more and the drive voltage (Vf) was 3.3 V or less.

In the semiconductor light-emitting device of Experimental Example 8 in which the translucent conductive film layer was not formed, the light emission output was 17.4 mW, which is lower than the light emission outputs of the semiconductor light-emitting devices of Experimental Examples 1 to 7.

In the semiconductor light-emitting device of Experimental Example 9 in which the translucent conductive film layer was formed in a thickness of 5 nm, the light emission output was 17.5 mW.

In the semiconductor light-emitting device of Experimental Example 10 in which the translucent conductive film layer was formed but the photocatalytic action-prevention layer was not formed, the light emission output was 18.1 mW, which is higher than the light emission output of the semiconductor light-emitting device of Experimental Example 8 in which the translucent conductive film layer was not formed, but is lower than the light emission output of the semiconductor light-emitting device of Experimental Example 1 in which the translucent conductive film layer and the photocatalytic action-prevention layer were both formed.

In the semiconductor light-emitting device of Experimental Example 11 in which neither the translucent conductive film layer nor the photocatalytic reaction-prevention layer were formed, the light emission output was 17.0 mW, which is lower than the light emission outputs of the semiconductor light-emitting devices of Experimental Examples 1 to 7.

In the semiconductor light-emitting device of Experimental Example 12 in which the concavo-convex pattern was not formed on the surface of the titanium oxide-based conductive film layer, the light emission output was 13.3 mW, which is the lowest among the light emission outputs of the semiconductor light-emitting devices of the respective Experimental Examples.

From the above results, it is apparent that the semiconductor light-emitting device of the present invention has excellent light extraction efficiency and high device characteristics.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor light-emitting device comprising an n-type semiconductor layer, a light-emitting layer, a p-type semiconductor layer, a titanium oxide-based conductive film layer, and a translucent conductive film layer laminated in this order, wherein
a concavo-convex surface is formed on at least a part of the surface of said titanium oxide-based conductive film layer.

2. The semiconductor light-emitting device according to claim 1, wherein said titanium oxide-based conductive film layer is of an oxide comprising Ti and at least one element selected from the group consisting of Ta, Nb, V, Mo, W, and Sb.

3. The semiconductor light-emitting device according to claim 1, wherein the refractive index of said translucent conductive film layer is within a range of 1.6 to 2.5.

4. The semiconductor light-emitting device according to claim 1, wherein said translucent conductive film layer is of a material comprising at least one selected from the group consisting of ITO (In₂O₃₋SnO₂), AZO (ZnO—Al₂O₃), IZO (In₂O₃—ZnO), and GZO (ZnO—Ga₂O₃).

5. The semiconductor light-emitting device according to claim 1, wherein said translucent conductive film layer is formed so as to cover said titanium oxide-based conductive film layer.

6. The semiconductor light-emitting device according to claim 1, wherein a photocatalytic reaction-prevention layer is additionally formed so as to cover said titanium oxide-based conductive film layer and said translucent conductive film layer.

7. The semiconductor light-emitting device according to claim 6, wherein the refractive index of said photocatalytic reaction-prevention layer is within a range of 1.5 to 2.0.

8. The semiconductor light-emitting device according to claim 6, wherein said photocatalytic reaction-prevention layer is made of silicon oxide or aluminum oxide.

9. The semiconductor light-emitting device according to claim 1, wherein the semiconductor light-emitting device is a nitride-based semiconductor light-emitting device.

10. The semiconductor light-emitting device according to claim 9, wherein said nitride-based semiconductor light-emitting device is a GaN-based semiconductor light-emitting device.

11. A method of manufacturing a semiconductor light-emitting device comprising an n-type semiconductor layer, a light-emitting layer, a p-type semiconductor layer, a titanium oxide-based conductive film layer, and a translucent conductive film layer laminated in this order,
the method comprising forming a concavo-convex surface on at least a part of the surface of said titanium oxide-based conductive film layer.

12. The method of manufacturing a semiconductor light-emitting device according to claim 11, wherein said translucent conductive film layer is formed so as to cover said titanium oxide-based conductive film layer.

13. The method of manufacturing a semiconductor light-emitting device according to claim 11, wherein a photocatalytic reaction-prevention layer is additionally formed so as to cover said titanium oxide-based conductive film layer and said translucent conductive film layer.

14. The method of manufacturing a semiconductor light-emitting device according to claim 13, wherein said photocatalytic reaction-prevention layer is formed by a sputtering method or a CVD method.

15. The method of manufacturing a semiconductor light-emitting device according to claim 14, wherein said photocatalytic reaction-prevention layer is formed by the CVD method using aluminum oxide.

16. A lamp comprising the semiconductor light-emitting device according to claim 1.

17. A lamp comprising a semiconductor light-emitting device obtained by the manufacturing method according to claim 11.
